(19) United States
(12) Patent Application Publication
(10) Pub. No.: US 2018/0264712 A1
(43) Pub. Date: Sep. 20, 2018

(54) IMPRINT METHOD AND TEMPLATE

(71) Applicant: Toshiba Memory Corporation, Tokyo (JP)

(72) Inventor: Masafumi ASANO, Yokohama (JP)

(73) Assignee: Toshiba Memory Corporation, Tokyo (JP)

(21) Appl. No.: 15/695,415

(22) Filed: Sep. 5, 2017

(30) Foreign Application Priority Data
Mar. 14, 2017 (JP) 2017-048981

(51) Int. Cl. B29C 59/04; H01L 21/033; B29C 59/00; B29C 43/56

(52) U.S. Cl. CPC B29C 59/046; H01L 21/0332; B05D 3/12; B29C 43/56; B29C 59/002

(57) ABSTRACT

According to an embodiment, an imprint method includes applying a resist above a substrate, and bringing a template having a concave-convex pattern into contact with the resist. Then, the imprint method includes positioning the template and the substrate with respect to each other, while monitoring an alignment mark provided on the template and an alignment mark provided on the substrate, by using an optical monitor under a state where the template is set in contact with the resist. Further, the imprint method includes monitoring a filling state of the resist into a recessed pattern provided on the template, by using the optical monitor under a state where the template is set in contact with the resist.

### CROSS-REFERENCE TO RELATED APPLICATIONS

This application is based upon and claims the benefit of priority from Japanese Patent Application No. 2017-048981, filed on Mar. 14, 2017; the entire contents of which are incorporated herein by reference.

### FIELD

Embodiments described herein relate generally to an imprint method and a template.

### BACKGROUND

An imprint method is a pattern forming method that brings a template into direct contact with a resist dropped on a substrate. In order to fill the resist into a pattern on the template. It is effective to set the template in contact with the resist dropped on the substrate by taking a sufficient time. However, if the imprint method requires a time more than necessary, the throughput will be lowered. Accordingly, it is desired to fill the resist in a time as short as possible.

In this respect, the filling time necessary and sufficient for the resist depends on the template engraving amount or the pattern dimensions. Accordingly, it is preferable to monitor the filling state of the resist during the imprint process so as to determine the filling end of the resist with an optimum time for every template. However, conventionally, there is no technique proposed to monitor the filling state of the resist.

### BRIEF DESCRIPTION OF THE DRAWINGS

FIG. 1 is a top view illustrating a structural example of a template;

FIG. 2 is a sectional view illustrating the structural example of the template;

FIG. 3 is a partial top view illustrating an example of a mark arrangement region of a template according to a first embodiment;

FIG. 4 is a partial sectional view schematically illustrating an example of the template according to the first embodiment;

FIG. 5 is a sectional view schematically illustrating a configuration example of an imprint apparatus;

FIG. 6 is a flowchart illustrating an example of the sequence of an imprint method according to the first embodiment;

FIGS. 7A to 7G are sectional views of the mark arrangement region, schematically illustrating the example of the sequence of the imprint method according to the first embodiment;

FIGS. 8A and 8B are top views schematically illustrating an example of the state of filling monitor marks according to the first embodiment before and after filling of a resist, respectively;

FIGS. 9A to 9F are sectional views schematically illustrating an example of the sequence of a template manufacturing method according to the first embodiment;

FIG. 10 is a partial sectional view schematically illustrating an example of a template according to a second embodiment; and

FIG. 11 is a block diagram illustrating a hardware configuration example of a controller.

### DETAILED DESCRIPTION

In general, according to one embodiment, an imprint method includes applying a resist above a substrate, and bringing a template having a concave-convex pattern into contact with the resist. Then, the imprint method includes positioning the template and the substrate with respect to each other, while monitoring an alignment mark provided on the template and an alignment mark provided on the substrate, by using an optical monitor under a state where the template is set in contact with the resist. Further, the imprint method includes monitoring a filling state of the resist into a recessed pattern provided on the template, by using the optical monitor under a state where the template is set in contact with the resist.

Exemplary embodiments of an imprint method and a template will be explained below in detail with reference to the accompanying drawings. The present invention is not limited to the following embodiments. The sectional views of a template used in the following embodiments are schematic, and so the relationship between the thickness and width of each layer and/or the thickness ratios between respective layers may be different from actual states.

### First Embodiment

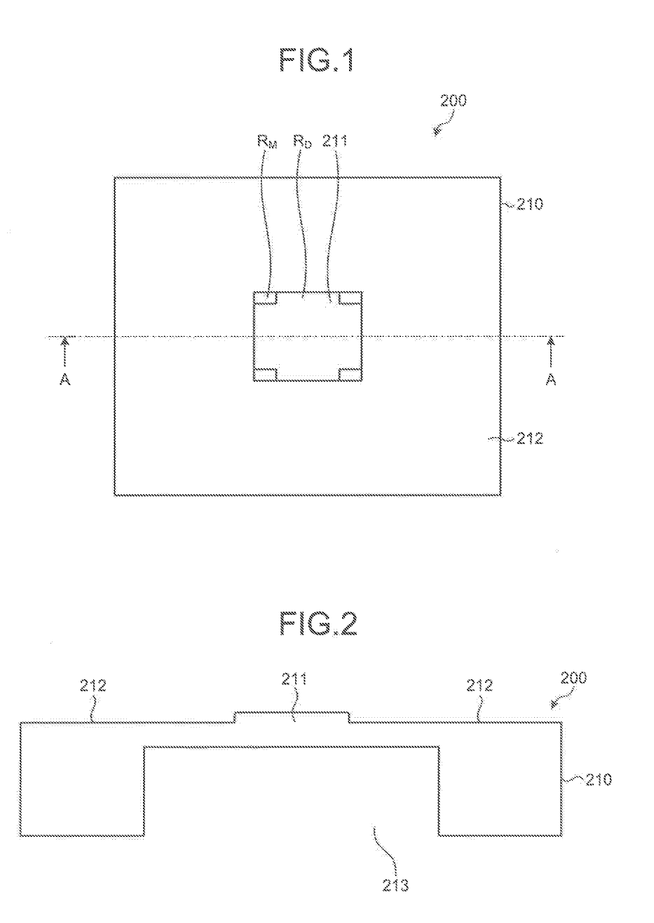

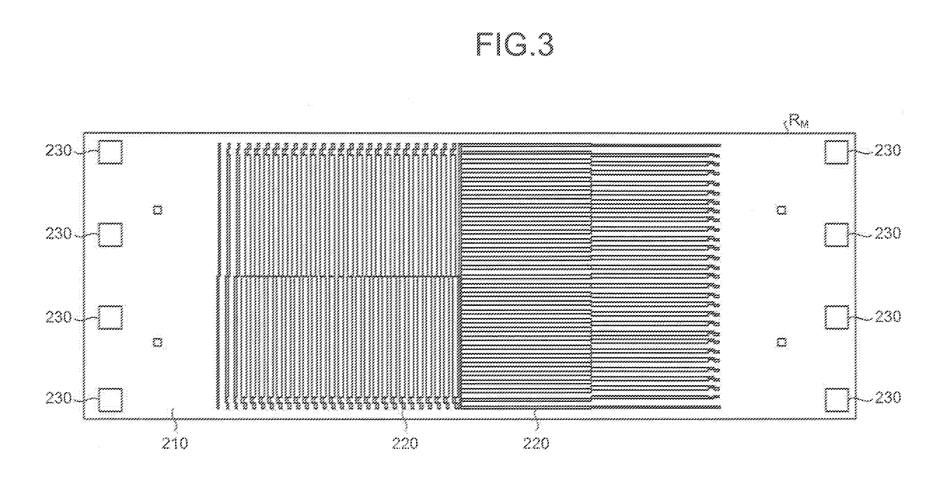

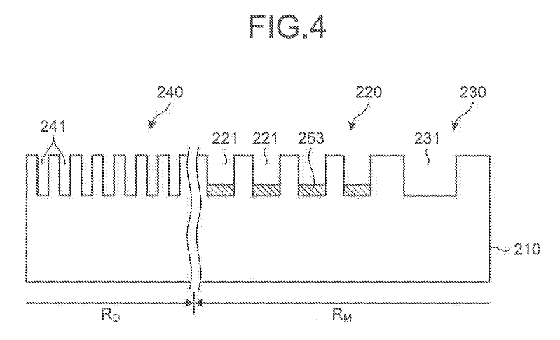

FIG. 1 is a top view illustrating a structural example of a template. FIG. 2 is a sectional view illustrating the structural example of the template, which is a sectional view taken along a line A-A of FIG. 1. FIG. 3 is a partial top view illustrating an example of a mark arrangement region of a template according to a first embodiment. FIG. 4 is a partial sectional view schematically illustrating an example of the template according to the first embodiment.

The template (original plate; mold) 200 has been prepared by processing a rectangular template substrate 210. The template substrate 210 includes a mesa part 211 and an off-mesa part 212 on the upper surface side, such that the mesa part 211 is at and near the center and serves as a pattern arrangement region provided with a rugged (concave-convex) pattern, and the off-mesa part 212 is disposed at a region other than the mesa part 211. The mesa part 211 has a mesa structure projected with respect to the off-mesa part 212. The mesa part 211 is configured to come in contact with a resist on a substrate (not shown) during an imprint process. Further, template substrate 210 includes a recessed part (bore) 213 formed in the lower surface. The recessed part 213 is arranged to include a region corresponding to the mesa part 211 that is on the upper surface side. The template substrate 210 is preferably made of a material that transmits ultraviolet rays. For example, the template substrate 210 is made of quartz.

The mesa part 211 includes a device formation pattern arrangement region R_{D}, in which a device formation pattern 240 for forming a device pattern on the substrate is arranged, and mark arrangement regions R_{M}, in which marks to be used during the imprint process are arranged. The device formation pattern arrangement region R_{D} is a region of the mesa part 211 other than the mark arrangement regions R_{M}. For example, the device formation pattern 240 includes line and space patterns or the like, in which recessed (concave) patterns 241 that extend are arranged at predetermined intervals in a direction intersecting with the extending direction.

The mark arrangement regions R_{M} are arranged, for example, near the corners (four corners) of the rectangular mesa part 211 serving as a pattern arrangement region. Each of the mark arrangement regions R_{M} is provided with alignment marks 220 for positioning the template 200 and the substrate with respect to each other, and filling monitor marks 230 for monitoring the filling state of the resist according to the first embodiment.

Each of the alignment marks 220 includes, for example, a diffraction grating pattern. For example, the diffraction grating pattern is composed of so-called line and space patterns, in which a plurality of recessed (concave) patterns 221 that extend are arranged in parallel with each other and at predetermined intervals in a direction intersecting with the extending direction. A refraction layer 253 is provided at the bottom of each of the recessed patterns 221. It is sufficient if the refraction layer 253 is made of a material different in refractive index from the template substrate 210. The refraction layer 253 may foe exemplified by a film of metal, such as Cr, Ta, Ti, or Ru; a film of metal nitride, such as TiN or TaN; a film of metal oxide, such as TaO; or a combination of these materials. Further, in the example of FIG. 3, two alignment marks 220 are arranged in each of the mark arrangement regions R_{M}, such that the extending directions of their diffraction grating patterns are orthogonal with each other.

The filling monitor marks 230 are arranged inside each of the mark arrangement regions R_{M}. For example, the filling monitor marks 230 are arranged near the peripheral portion of each of the mark arrangement regions R_{M}. When position adjustment is performed by using the alignment marks 220, the alignment marks 220 are monitored by an optical monitor provided in an imprint apparatus described later. The filling monitor marks 230 are arranged at positions where they are to be present together with the alignment marks 220 inside the field of view of the optical monitor at the time of monitoring described above. The filling monitor marks 230 are arranged near the alignment marks 220 so that they can enter the field of view of the optical monitor in this way. If it is assumed that each mark arrangement region R_{M} corresponds to the field of view of the optical monitor, the filling monitor marks 230 are arranged inside the mark arrangement region R_{M}, and are not arranged inside the device formation pattern arrangement region R_{D}. Here, the optical monitor is exemplified by a camera or microscope.

The filling monitor marks 230 are patterns to be used, in the imprint process, for determining whether the resist has been filled in the device formation pattern 240 formed in the device formation pattern arrangement region R_{D}. Accordingly, the filling monitor marks 230 are composed of patterns that have a filling time equal to a filling completion time by which filling of the resist into the device formation pattern 240 is completed. The filling completion time is determined on the basis of the engraving amount or the pattern dimensions of the device formation pattern 240. The filling time may be set equal to the filling completion time, or set slightly larger than the filling completion time in consideration of some margin.

Each of the filling monitor marks 230 may have any shape, as long as it can be filled with the resist by using the filling time described above. For example, when seen in a plan view, each filling monitor mark 230 may be composed of a recessed pattern having a rectangular shape, may be composed of a recessed pattern having an elongated shape, or may be composed of so-called line and space patterns, in which a plurality of recessed patterns that extend are arranged in parallel with each other in a direction intersecting with the extending direction. In the example illustrated in FIGS. 3 and 4, each filling monitor mark 230 is composed of a recessed (concave) pattern 231 having a rectangular shape, when seen in a plan view. Further, unlike the alignment marks 220, the refraction layer 253 is not provided at the bottom of each of the recessed patterns 231 composing the filling monitor marks 230.

As illustrated in FIG. 4, the recessed patterns 241 composing the device formation pattern 240, the recessed patterns 221 composing the alignment marks 220, and the recessed patterns 231 composing the filling monitor marks 230 have depths equal to each other. Accordingly, in the first embodiment, adjustment on the filling time of each filling monitor mark 230 is performed by adjusting its size in the substrate surface direction of the template substrate 210.

Next, an explanation will be given of an imprint method using the template 200 described above. In the imprint method, an imprint apparatus is employed. Thus, hereinafter, a schematic configuration of the imprint apparatus will be first described, and the imprint method using the imprint apparatus will be then described.

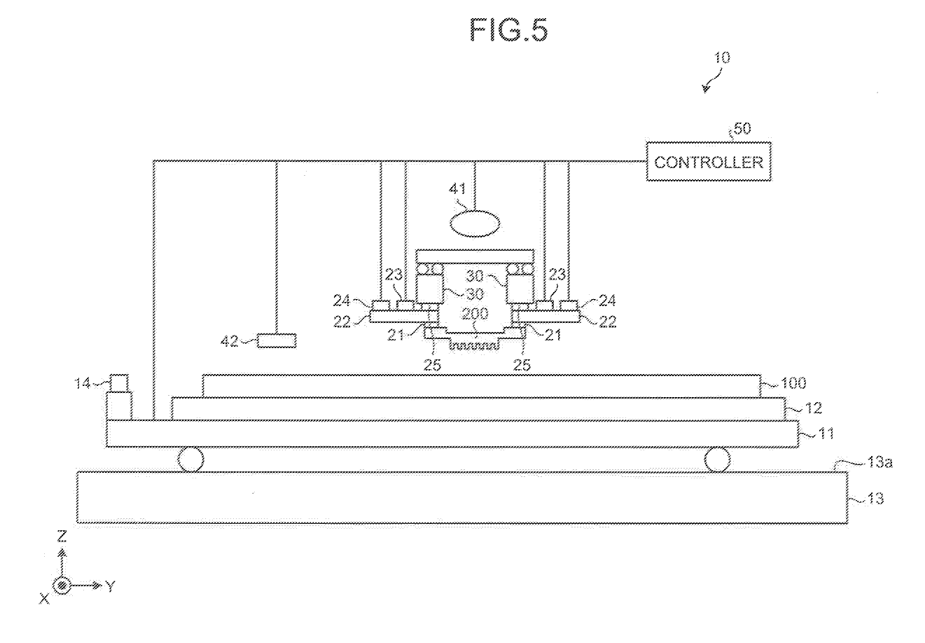

FIG. 5 is a sectional view schematically illustrating a configuration example of the imprint apparatus. The imprint apparatus 10 includes a substrate stage 11. The substrate stage 11 is provided with a chuck 12. The chuck 12 is configured to hold a substrate 100 treated as a pattern formation object. The chuck 12 holds the substrate 100 by means of, for example, vacuum suction. A substrate bolder includes the substrate stage 11 and the chuck 12.

The substrate 100 includes a substrate (wafer), such as a semiconductor substrate, an underlying pattern formed on this substrate, and a process target layer formed on this underlying pattern. When pattern transfer is performed, the substrate 100 further includes a resist formed on the process target layer. As the process target layer, an insulating film, metal film (conductive film), or semiconductor film may be cited.

The substrate stage 11 is provided to be movable on a stage bed 13. The substrate stage 11 is arranged to be movable along respective ones of two axes that extend along the upper surface 13a of the stage bed 13. Here, the two axes that extend along the upper surface 13a of the stage bed 13 will be referred to as “X-axis” and “Y-axis”. The substrate stage 11 is further arranged to be movable in the height direction that will be referred to as “Z-axis”, which is orthogonal with the X-axis and the Y-axis. The substrate stage 11 is preferably arranged to be rotatable about each of the X-axis, the Y-axis, and the Z-axis.

The substrate stage 11 is provided with a reference mark pedestal 14. A reference mark (not shown) is disposed at the top of the reference mark pedestal 14, and is used as a reference position for the imprint apparatus 10. For example, the reference mark is composed of a diffraction grating having a checkered pattern. The reference mark is used for performing calibration of alignment scopes 30 and positioning (attitude control and adjustment) of the template 200. The reference mark serves as the original point of the substrate stage 11. The X- and Y-coordinates of the substrate 100 placed on the substrate stage 11 are coordinates using the reference mark pedestal 14 as the original point.

The imprint apparatus 10 includes a template stage 21. The template stage 21 is configured to fix the template 200. The template stage 21 holds the peripheral portion of the template 200 by means of, for example, vacuum suction. The template stage 21 operates to position the template 200 with reference to the apparatus. The template stage 21 is attached to a base part 22.

A correction mechanism 23 and a pressurizing section 24 are mounted on the base part 22. The correction mechanism 23 includes an adjustment mechanism for slightly adjusting the position (attitude) of the template 200 in accordance with an instruction received from, for example, a controller 50. With this adjustment, the relative positions of the template 200 and the substrate 100 therebetween are corrected.

The pressurizing section 24 applies stress to the side surfaces of the template 200 to straighten distortion of the template 200. The pressurizing section 24 applies pressure to the template 200 from the four side surfaces of the template 200 toward the center. With this pressure application, the dimensions of a pattern to be transferred are corrected (magnification correction). The pressurizing section 24 applies pressure to the template 200 with a predetermined stress in accordance with an instruction received from, for example, the controller 50.

The base part 22 is attached to the alignment stage 25. The alignment stage 25 moves the base part 22 in the X-axis direction and the Y-axis direction to position the template 200 and the substrate 100 with respect to each other. The alignment stage 25 also has a function to rotate the base part 22 along an XY-plane. The rotational direction along the XY-plans will be referred to as “θ-direction”. Here, a template holder includes the template stage 21, and may further include the base part 22, the correction, mechanism 23, the pressurizing section 24, and the alignment stage 25 in addition.

Each of the alignment scopes 30 serves as an optical monitor for detecting the alignment marks 220 provided on the template 200 and alignment marks provided on the substrate 100. The alignment marks of the substrate 100 and the alignment marks 220 of the template 200 are used to measure relative positional deviation between the template 200 and the substrate 100. Here, the respective alignment scopes 30 are preferably arranged at positions corresponding to the four corners of the mesa part 211 of the template 200, to simultaneously pick up images of the alignment marks 220 arranged at the four corners of the mesa part 211.

Further, in the first embodiment, each of the alignment scopes 30 is adjusted to have a field of view such that the filling monitor marks 230 are included inside the field of view when the alignment marks provided on the template 200 are detected. Here, each of the alignment scopes 30 may include an imaging unit for picking up an image of the field of view being monitored.

The imprint apparatus 10 includes a light source 41 and a coating member 42. The light source 41 emits electromagnetic waves, for example, within the ultraviolet region. The light source 41 is arranged to be right above the template 200, for example. In another case, the light source 41 may be not arranged right above the template 200. In this case, an optical path is set by using an optical component, such as a mirror, so that light emitted from the light source 41 can be radiated from right above the template 200 toward the template 200. The light source 41 turns on or off the light irradiation to the template 200 in accordance with an instruction received from, for example, the controller 50.

The coating member 42 is a member for applying a resist onto the substrate 100. For example, the coating member 42 is formed of an Inkjet head including a nozzle, and is configured to drop the resist from the nozzle onto the substrate 100. The resist used in the first embodiment has a refractive index equivalent to the refractive index of the template 200. It should be noted that the “equivalent to” used here encompasses not only a state completely equal to each other but also a state slightly different from each other. The coating member 42 drops the resist onto a predetermined position on the substrate 100 in accordance with an instruction received from, for example, the controller 50.

The imprint apparatus 10 includes the controller 50. The controller 50 performs overall control of the imprint apparatus 10. For example, the controller 50 executes a control process for the substrate stage 11, a control process for the light source 41, a positional deviation correcting process, a template height arithmetic process, a magnification correcting process, and so forth, in accordance with programs prescribing the contents of the respective processes.

The control process for the substrate stage 11 is a process of generating a signal for controlling the substrate stage 11 in the X-axis direction, the Y-axis direction, the Z-axis direction, and the θ-direction. With this process, the relative positions of the template 200 and the substrate stage 11 therebetween are controlled. The control process for the light source 41 is a process of controlling the light irradiation timing or irradiation amount used by the light source 41 when the resist is cured.

In the positional deviation correcting process, the alignment marks of the template 200, and the reference mark of the reference mark pedestal 14 or the alignment marks of the substrate 100 are used, to obtain a positional deviation of the template 200 relative to the reference mark, and to obtain a positional deviation of the substrate 100 relative to the template 200. Then, on the basis of these positional deviations, an arithmetic operation for achieving alignment between the template stage 21 and the substrate stage 11 is performed, and the positional deviations are thereby corrected.

In the template height arithmetic process, the alignment marks of the template 200, and the alignment marks of the substrate 100 or the reference mark of the reference mark pedestal 14 are used, to perform an arithmetic operation for calculating the template height at the alignment mark formation positions of the template 200.

In the magnification correcting process, a predetermined arithmetic operation is performed on the basis of the template height, to calculate a stress for performing magnification correction to the template 200. Then, a signal for generating this stress is given to the pressurizing section 24.

Further, the controller 50 performs a filling completion determination process for determining whether filling of the resist into the pattern has been completed, by using the filling monitor marks 230, when performing a positioning process between the template 200 and the substrate 100. Before the imprint process is started, the recessed patterns 231 of the filling monitor marks 230 are filled with air, which has a refractive index different from the refractive index of the template 200. Accordingly, at this time, the contours of the filling monitor marks 230 can be confirmed by the alignment scopes 30. On the other hand, the refractive index of the resist is almost equal to the refractive index of the template 200. Thus, after the imprint process is started, and when the inside of the recessed patterns 231 is entirely filled with the resist, the contours of the filling monitor marks 230 cannot be confirmed any more.

In consideration of this, the controller 50 specifies the positions of the filling monitor marks 230 from inside an image monitored by each of the alignment scopes 30, and monitors the contrast of the filling monitor marks 230 relative to a region other than the filling monitor marks 230. Then, when the contrast of the filling monitor marks 230 becomes lower than a predetermined value, the controller 50 determines that filling of the resist into the recessed patterns 241 of the device formation pattern 240 has been completed.

This determination process is performed by picking up an image including the filling monitor marks 230, for example, by each of the alignment scopes 30, and comparing the picked-up linage with a reference image for enabling a judgment about the filling completion of the resist. When the contrast of the recessed patterns 231 of the picked-up image is lower than the contrast of the recessed patterns 231 of the reference image, the controller 50 determines that filling of the resist into the recessed patterns 241 has been completed. On the other hand, when the contrast of the recessed patterns 231 of the picked-up image is higher than the contrast of the recessed patterns 231 of the reference image, the controller 50 determines that filling of the resist into the recessed patterns 241 has not yet been completed.

Alternatively, a value representing the contrast of the recessed patterns 231 of the picked-up image may be compared with a predetermined reference value for enabling a judgment about the filling completion of the resist. This is intended to detect disappearance of the contours of the recessed patterns 231, because the contours of the recessed patterns 231 disappear when the inside of the recessed patterns 231 is filled with the resist.

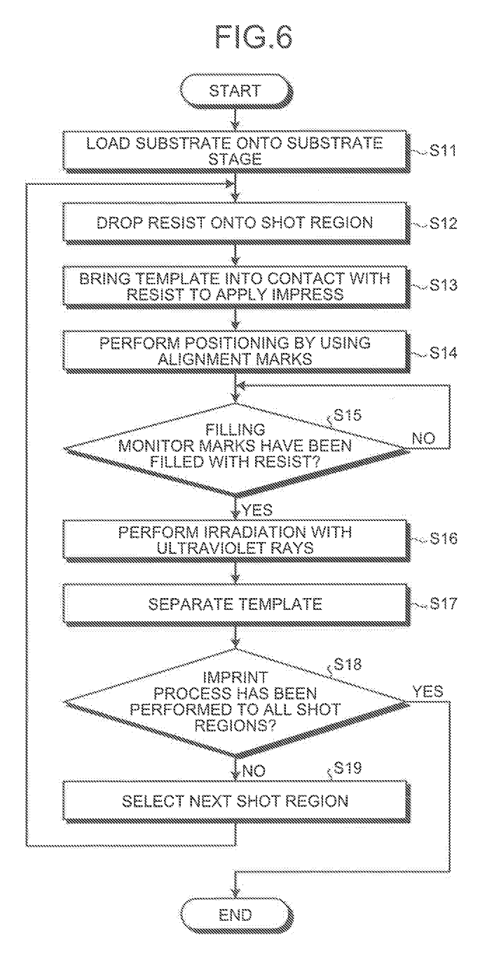

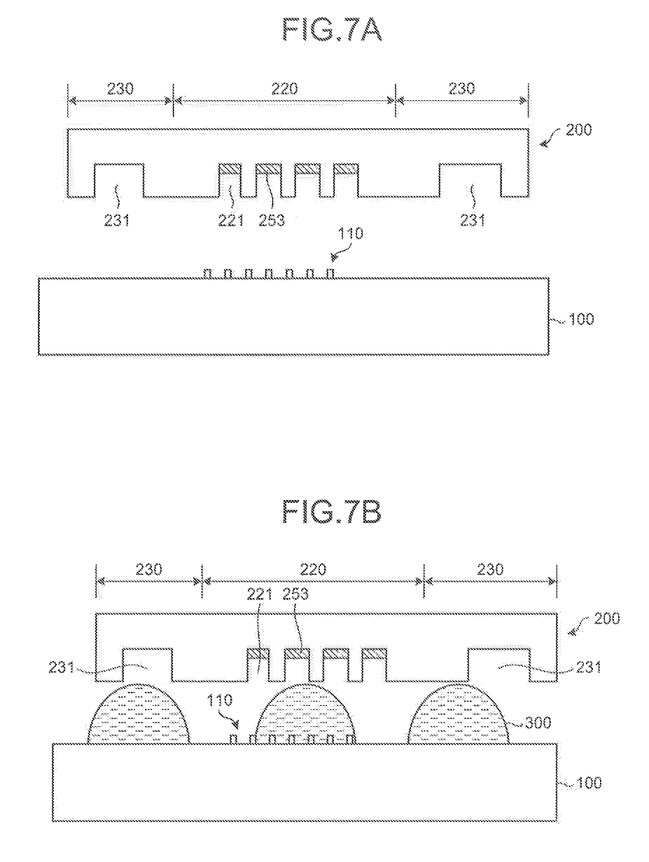

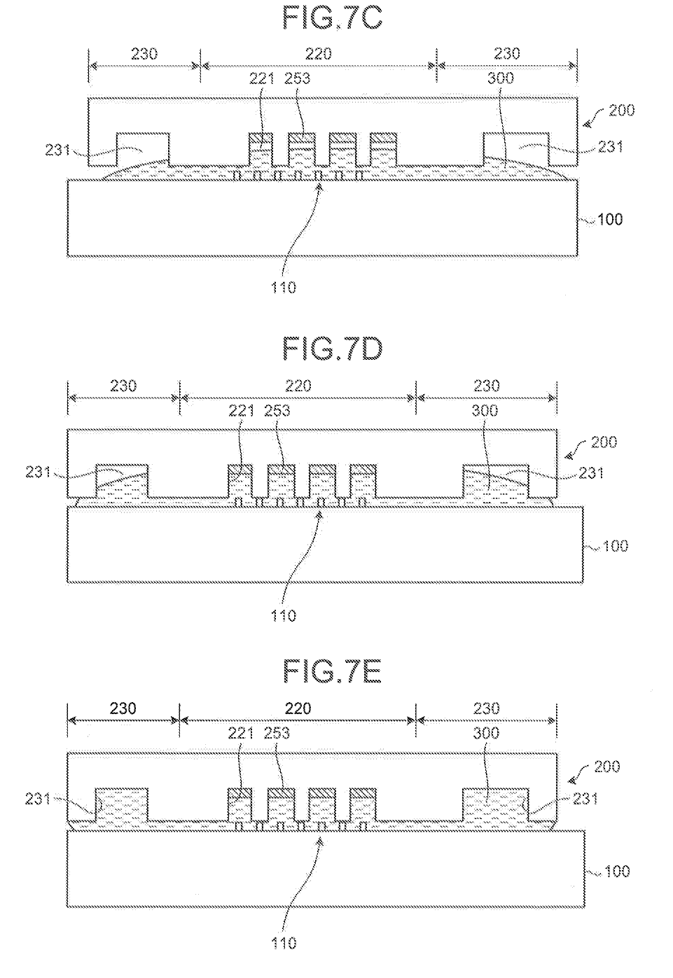

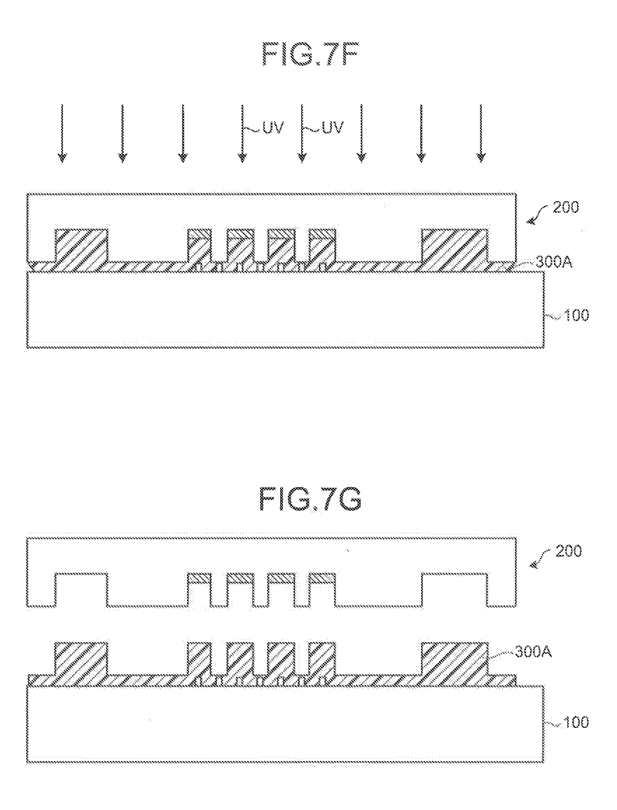

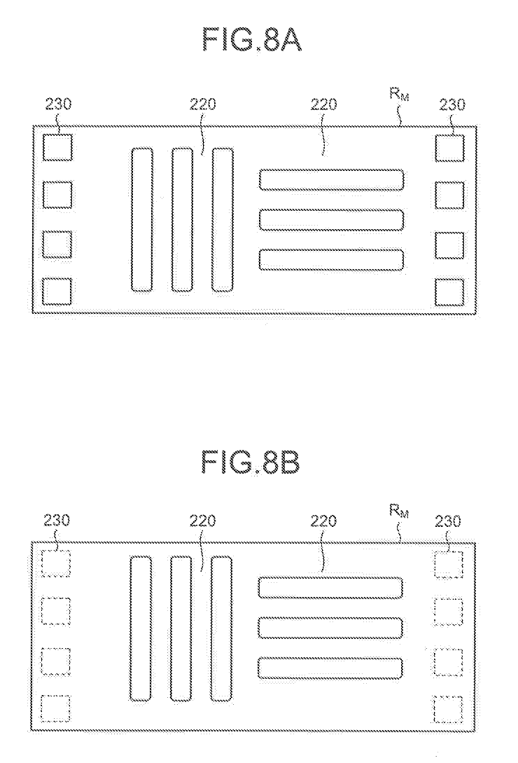

FIG. 6 is a flowchart illustrating an example of the sequence of an imprint method according to the first embodiment. FIGS. 7A to 7G are sectional views of the mark arrangement region, schematically illustrating the example of the sequence of the imprint method according to the first embodiment. FIGS. 8A and 8B are top views schematically illustrating an example of the state of filling monitor marks according to the first embodiment before and after filling of a resist, respectively. Here, FIGS. 7A to 7G and 8A and 8B illustrate only a mark arrangement region R_{M}. Further, the controller 50 controls operations of the respective components of the imprint apparatus 10 in accordance with the flowchart described below.

First, the substrate 100 is loaded onto the substrate stage 11 of the imprint apparatus 10 (step S11 and FIG. 7A). Then, a resist 300 is dropped from the coating member 42 onto a target shot region of the substrate 100 (step S12 and FIG. 7B). Here, the shot region denotes a region on the substrate 100 that the mesa part 211 of the template 200 comes into contact with in the imprint process.

Thereafter, the template 200 is moved down and brought into contact with the resist 300 on the substrate 100 to apply an impress (step S13 and FIG. 7C). Further, in this impress process to the resist 300, a positioning process between the template 200 and the substrate 100 is performed by using the alignment marks 220 (step S14 and FIG. 7D). In this positioning process, the alignment marks 220 of the template 200 and alignment marks 110 of the substrate 100 are monitored by using the alignment scopes 30. Then, in accordance with this monitoring result, the controller 50 performs the positioning process. For example, the substrate stage 11 is moved by the stage bed 13 in a necessary direction among the X-axis, the Y-axis, and the Z-axis.

At this time, an image of each mark arrangement region R_{M} picked up by the corresponding alignment scope 30, i.e., the field of view monitored by the alignment scope 30, is in a state as illustrated in FIG. 8A, for example. In FIG. 8A, the image pickup range (the field of view) of the alignment scope 30 corresponds to the inside of the mark arrangement region R_{M} including the alignment marks 220 and the filling monitor marks 230.

Further, in the resist impress process, it is determined whether the filling monitor marks 230 nave been filled with the resist 300 (step S15). Specifically, when the filling monitor marks 230 are not filled with the resist 300, the filling monitor marks 230 are in a state that can be visually confirmed in the image picked up in step 314, as illustrated in FIG. 8A. This is because there is a difference in refractive index between air present in the filling monitor marks 230 and the template substrate 210. However, as illustrated in FIG. 8B, when the inside of the filling monitor marks 230 is filled with the resist 300, the contours of the filling monitor marks 230 can be hardly visually confirmed in the image picked up by the alignment scope 30. This is because the refractive index of the resist 300 filled in the filling monitor marks 230 is almost equal to the refractive index or the template substrate 210. Further, as the resist 300 infiltrates into the filling monitor marks 230, the visually confirmable level of the filling monitor marks 230 varies depending on the infiltration degree. Accordingly, it is possible to determine whether the filling monitor marks 230 have been filled with the resist 300 by determining whether the filling monitor marks 230 can be visually confirmed. Here, the determination as to whether the filling monitor marks 230 have been filled with the resist 300 is performed, for example, by comparing the picked-up image of the filling monitor marks 230 with the reference image, in terms of the contrast of the filling monitor marks 230, as described above.

When the filling monitor marks 230 have not been filled with the resist 300 (No at step S15), the filling monitor marks 230 are in a state that can be visually confirmed. Accordingly, this is treated as a state to wait until the filling monitor marks 230 are filled (FIG. 7E).

On the other hand, when the filling monitor marks 230 have been filled with the resist 300 (Yes at step S15), the filling monitor marks 230 are in a state where their contours cannot be visually confirmed from the image picked up by the alignment scope 30, as illustrated in FIG. 8B. Specifically, when the inside of the filling monitor marks 230 has been filled with the resist 300, this indicates that the resist 300 has been filled in the recessed patterns 241 of the device formation pattern 240 of the template 200. Then, the resist 300 is irradiated with ultraviolet rays UV from the light source 41 (step S16 and FIG. 7F). Consequently, the resist 300 impressed with the template 200 is cured into a resist 300A. After the irradiation with ultraviolet rays UV is performed for a predetermined time, the template 200 is separated from the substrate 100 (step S17 and FIG. 7G). As a result, the patterns provided on the template 200 are transferred onto the resist 300A.

Then, it is determined whether the imprint process has been performed to all the shot regions (step S18). When the imprint process has not yet been performed to all the shot regions (No at step S18), the next shot region is selected (step S19), and the process goes back to step S12. On the other hand, when the imprint process has been performed to all the shot regions (Yes at step S18), the process ends.

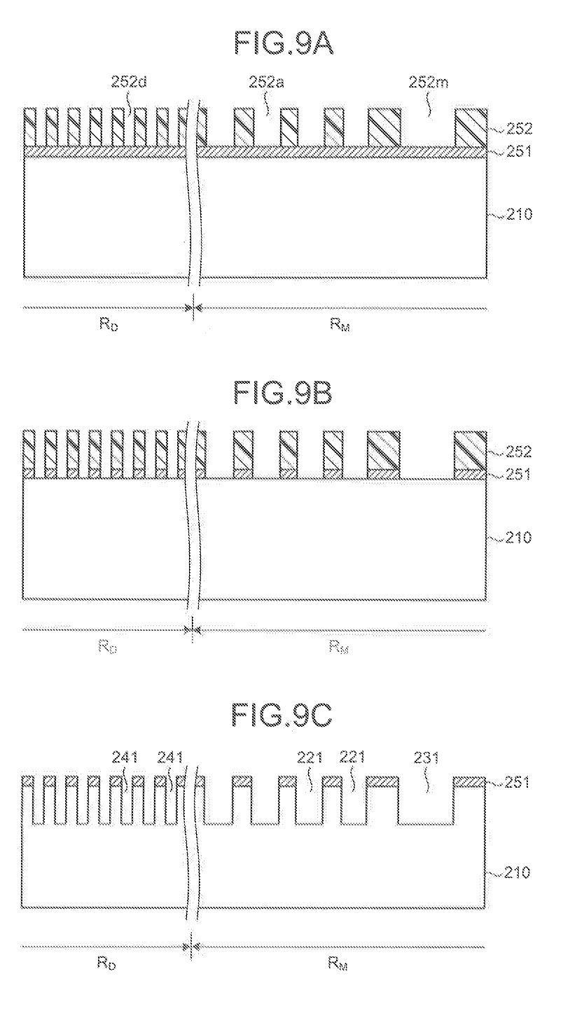

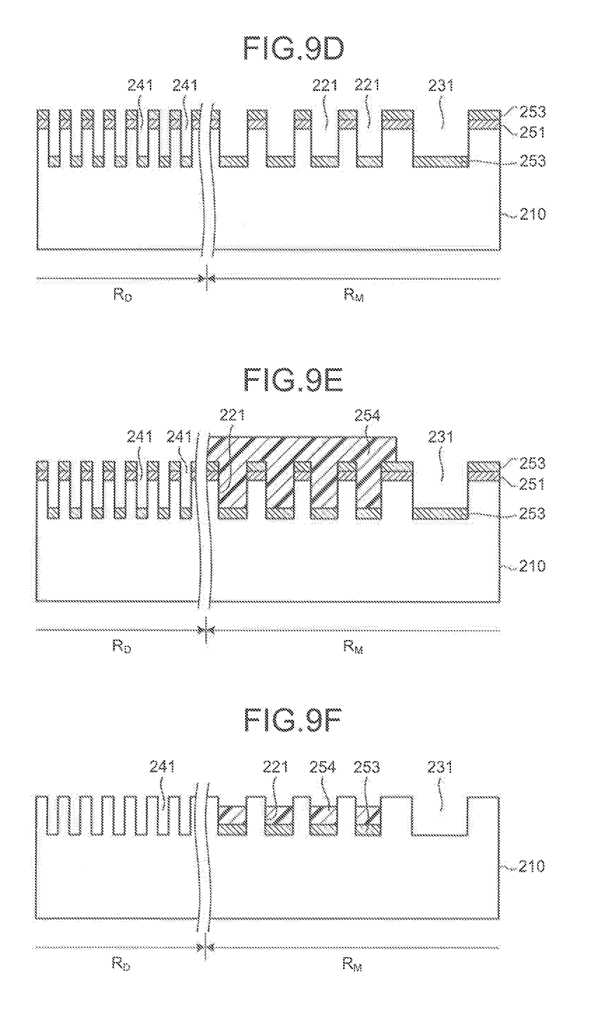

Next, an explanation will be given of a manufacturing method of the template 200 described above. FIGS. 9A to 9F are sectional views schematically illustrating an example of the sequence of a template manufacturing method according to the first embodiment. First, as illustrated in FIG. 9A, a template substrate 210 is prepared, and a hard mask film 251 is formed on the upper surface of the template substrate 210. As the template substrate 210, for example, a synthetic quarts substrate or the like may be used. Further, as the hard mask film 251, for example, a film of metal, such as Cr, Ta, Ti, or Ru; a film of metal nitride, such as TiN or TaN; a film of metal oxide, such as TaO; or a combination thereof may be used. Here, the hard mask film 251 is set to have a thickness of 15 nm, for example.

Further, a resist 252 is applied onto the hard mask film 251, and patterning is performed to the resist 252 by using an EB drawing technique and a development technique. Here, patterns are formed in the device formation pattern arrangement region R_{D} and the mark arrangement regions R_{M}. In the device formation pattern arrangement region R_{D}, recessed patterns 252d for forming a device formation pattern 240 are formed. In each mark arrangement region R_{M}, recessed patterns 252a to be alignment marks 220 and recessed patterns 252m to be filling monitor marks 230 are formed.

Thereafter, as illustrated in FIG. 9B, the hard mask film 251 is processed through the patterned resist 252 serving as a mask, by using anisotropic etching, such as an RIE (Reactive Ion Etching) method.

Further, as illustrated in FIG. 9C, the template substrate 210 is processed through the patterned resist 252 and hard mask film 251 serving as a mask, by using anisotropic etching, such as an RIE method. The processing depth may be set to 60 nm, for example. Consequently, recessed patterns 221 to be the alignment marks 220 and recessed patterns 231 to be the filling monitor marks 230 in each mark arrangement region R_{M}, and recessed patterns 241 in the device formation pattern arrangement region R_{D} are simultaneously formed. Thereafter, the resist 252 is peeled by using a resist peeling technique.

Then, as illustrated in FIG. 9D, a refraction layer 253 is formed on the upper surface of the template substrate 210. This refraction layer 253 is also formed at the bottom of the recessed patterns 221, 231, and 241. The refraction layer 253 may be exemplified by a film of metal, such as Cr, Ta, Ti, or Ru; a film of metal nitride, such as TiN or TaN; a film of metal, oxide, such as TaO; or a combination of these materials.

Then, as illustrated in FIG. 9F, a resist 254 is applied onto the upper surface of the template substrate 210. The resist 254 is formed to cover the respective recessed patterns 221, 231, and 241. Thereafter, patterning is performed to the resist 254, by using an EB drawing technique and a development technique, such that a portion of the resist 254 remains only on each of the arrangement regions for the recessed patterns 221 to be the alignment marks 220 in each mark arrangement region R_{M}.

Thereafter, as illustrated in FIG. 9F, in the regions not masked by the resist 254, the portions of the refraction layer 253 inside the recessed patterns 241 in the device formation pattern arrangement region R_{D}, and the portions of the refraction layer 253 inside the recessed patterns 231 that compose the filling monitor marks 230 in each mark arrangement region R_{M} are removed by using anisotropic etching, such as an RIE method. Further, the portions of the hard mask film 251 and refraction layer 253 deposited on the upper surface of the template substrate 210 are removed over the entire surface of the template substrate 210.

Then, the resist 254 is peeled by using a resist peeling technique, and the template 200 having the structure illustrated in FIG. 4 is thereby obtained.

According to the first embodiment, the template 200 is used that includes the mark arrangement regions R_{M}, in each of which the alignment marks 220 are arranged together with the filling monitor marks 230. Further, the filling monitor marks 230 are arranged to be included in the field of view that monitors the alignment marks 220 in the imprint process. When the inside of the filling monitor marks 230 is filled with the resist 300, the filling monitor marks 230 disappear, because the refractive index of the resist 300 and the refractive index of template 200 are almost equal to each other. As a result, by monitoring the filling state during the imprint process, it is achieved to provide an effect capable of determining the filling end of the resist 300, with an optimum time for every template 200.

Further, when the impress process is performed continuously for a predetermined rime and then is shifted to a curing process for the resist 300, there is a case where filling of the resist 300 has not yet been completed within the predetermined time, or filling of the resist 300 has already been completed earlier than the predetermined time. However, in the first embodiment, the filling monitor marks 230 are used to determine the filling end of the resist 300. Thus, if filling of the resist 300 is completed before the predetermined time, the impress process can be shifted to the next process at the time point of this determination. On the other than, if filling of the resist 300 has not yet been completed within a lapse of the predetermined time, the impress process can be prolonged. Further, the impress process can be shifted to the next curing process for the resist 300 at the time point of determination made by using the filling monitor marks 230 that filling of the resist 300 has been completed. Thus, it is possible to prevent occurrence of a state where filling of the resist 300 has not been completed in each impress process.

Further, the filling monitor marks 230 are arranged near the alignment marks 220. With this arrangement, the positioning process using the alignment marks 220 and the monitoring process to the filling monitor marks 230 are simultaneously performed during the imprint process. Thus, it is possible to perform the imprint process with a necessary minimum time, and thereby to suppress the productivity loss.

Further, the mark arrangement regions R_{M} are arranged at the four corners of the rectangular mesa part 211, and each of the mark arrangement regions R_{M} is provided with the filling monitor marks 230. In the imprint method, it is thought that filling of the resist 300 develops from the center of the template 200. Accordingly, by monitoring the filling monitor marks 230 arranged at the four corners of the rectangular mesa part 211, it is achieved to provide an effect capable of accurately monitoring the filling state over the entire surface of the template 200.

### Second Embodiment

In the first embodiment, the depth of the filling monitor marks is equal to the depth of the alignment marks and device formation pattern. In the second embodiment, an explanation will be given of a case where the depth of the filling monitor marks is different from the depth of the alignment marks and device formation pattern in terms of the engraving amount.

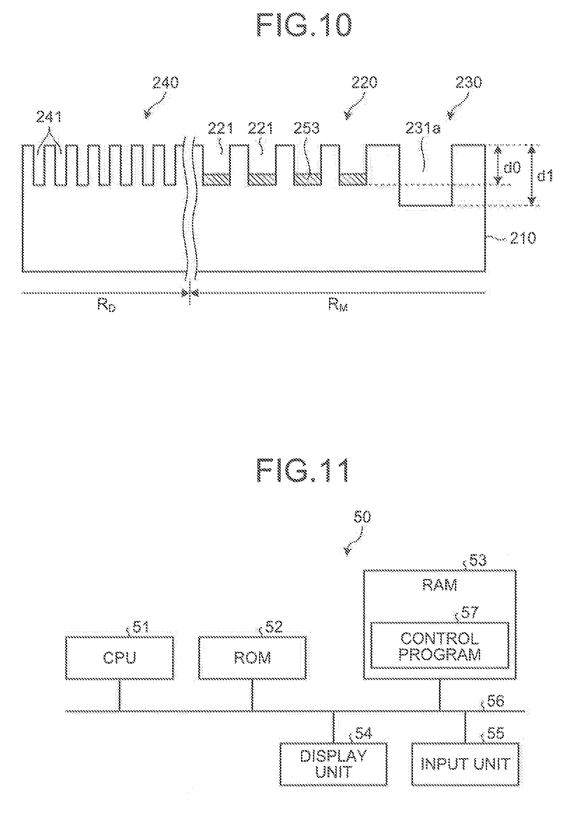

FIG. 10 is a partial sectional view schematically illustrating an example of a template according to the second embodiment. In FIG. 10, the depth of the recessed patterns 221 of the alignment marks 220 and the depth of the recessed patterns 241 composing the device formation pattern 240 are both set to d0, but the depth of the recessed patterns 231a of the filling monitor marks 230 is set to d1 larger than d0, For example, when the depth d0 is set to 60 nm at the recessed patterns 221 and 241 that compose the alignment marks 220 and the device formation pattern 240, the depth d1 may be set to 100 nm at the recessed patterns 231a of the filling monitor marks 230.

As the recessed patterns 231a of the filling monitor marks 230 are set deeper than the recessed patterns 221 and 241 of the other regions as described above, the filling completion of the resist is delayed at the filling monitor marks 230, as compared with the other recessed patterns 221 and 241, in the imprint process. In other words, the time until the filling monitor marks 230 are filled with the resist can be set longer than that of the first embodiment. Accordingly, when the filling monitor marks 230 have been normally filled with the resist, this indicates that the other patterns, particularly the device formation pattern 240, have been filled with the resist.

Here, the constituent elements corresponding to those described in the first embodiment, are denoted by the same reference symbols, and their description will be omitted. Further, an imprint method according to the second embodiment is the same as that described in the first embodiment, and so its description will be omitted.

This template 200 is manufactured, for example, by separating a step of forming the filling monitor marks 230 from a step of forming the alignment marks 220 and the device formation pattern 240. For example, first, the regions other than the arrangement regions for the filling monitor marks 230 are masked, and the filling monitor marks 230 having the depth d1 are formed. Then, the arrangement regions for the filling monitor marks 230 are masked, and patterns in the other regions, such as the alignment marks 220 and the device formation pattern 240, are formed. Here, the above is a mere example, and may be modified such that the alignment marks 220 and the device formation pattern 240 are formed first, and the filling monitor marks 230 are formed thereafter.

According to the second embodiment, the engraving amount of the filling monitor marks 230 is set larger than the engraving amount of the other recessed patterns 221 and 241 arranged on the template 200. The filling monitor marks 230 are the most difficult to fill, as compared with the other recessed patterns 221 and 241. Accordingly, by making reference to that the filling monitor marks 230 have been normally filled, it is achieved to provide an effect capable of assuring that the other recessed patterns 221 and 241 have been filled.

Incidentally, each of the above embodiments is exemplified by a case where the refraction layer 253 at the bottom of the recessed patterns 221 of the alignment marks 220 is made of a film of metal, such as Cr, Ta, Ti, or Ru; a film of metal nitride, such as TiN or TaN; a film of metal oxide, such as TaO; or a combination of these materials. However, the refraction layer 253 may be formed by implanting ions of metal, such as Cr, Ta, Ti, or Ru, into portions of the template substrate 210 at positions near the bottom of the recessed patterns 221, by using an ion implantation method.

Next, an explanation will be given of a hardware configuration of the controller 50 in the imprint apparatus 10 according to each of the first and second embodiments. FIG. 11 is a block diagram illustrating a hardware configuration example of the controller. The controller 50 includes a CPU (Central Processing Unit) 51, a ROM (Read Only Memory) 52, a RAM (Random Access Memory) 53, a display unit 54, and an input unit 55. In the controller 50, the CPU 51, the ROM 52, the RAM 53, the display unit 54, and the input unit 55 are connected to each other via a bus line 56.

A control program 57 for executing the imprint method according to the first or second embodiment in the imprint apparatus 10 is stored, for example, in the ROM 52. The CPU 51 loads the control program 57 stored, for example, in the ROM 52 into the RAM 53, and executes the control program 57. Here, the control program 57 is provided in a state recorded in a computer-readable recording medium, such as a CD-ROM (Compact Disk ROM), flexible disk (Flexible Disk: FD), CD-R (CD Recordable), or DVD (Digital Versatile Disk), by a file in an installable format or executable format.

While certain embodiments have been described, these embodiments have been presented by way of example only, and are not intended to limit the scope of the inventions. Indeed, the novel embodiments described, herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An imprint method comprising:
applying a resist above a substrate;
bringing a template having a concave-convex pattern into contact with the resist;
positioning the template and the substrate with respect to each other, while monitoring an alignment mark provided on the template and an alignment mark provided on the substrate, by using an optical monitor under a state where the template is set in contact with the resist; and
monitoring a filling state of the resist into a recessed pattern provided on the template, by using she optical monitor under a state where the template is set in contact with the resist.

2. The imprint method according to claim 1, wherein the positioning and the monitoring the filling state of the resist are simultaneously performed.

3. The imprint method according to claim 2, wherein in the positioning and the monitoring the filling state of the resist, the alignment mark of the template and the recessed pattern are present inside a field of view of the optical monitor.

4. The imprint method according to claim 1, wherein, in the monitoring the filling state of the resist, it is determined whether to continue or finish a state where the template is set in contact with the resist, on a basis of a monitoring result about the filling state of the resist into the recessed pattern.

5. The imprint method according to claim 4, wherein the monitoring the filling state of the resist includes
picking up an image of a field of view including the recessed pattern by the optical monitor, and,
determining, when a coat rest of the recessed pattern obtained from the image is higher than a predetermined value, to continue the state where the template is set in contact with the resist.

6. The imprint method according to claim 4, further comprising:
curing the resist under the state where the template is set in contact with the resist, after the monitoring the filling state of the resist, wherein
the monitoring the filling state of the resist includes
picking up an image of a field of view including the recessed pattern by the optical monitor, and,
determining, when a contrast of the recessed pattern obtained from the image is lower than a predetermined value, to proceed to the curing.

7. The imprint method according to claim 1, wherein the resist has a refractive index equivalent to a refractive index of the template.

8. A template comprising:
a template substrate;
a device formation pattern including a first recessed pattern provided on the template substrate;
an alignment mark including a second recessed pattern provided on the template substrate, at a surface common to the device formation pattern, and
a filling monitor mark including a third recessed pattern provided on the template substrate, at the surface common to the device formation pattern;
wherein the alignment mark includes a refraction layer provided at a bottom of the second recessed pattern, and
the filling monitor mark is arranged near the alignment mark.

9. The template according to claim 8, wherein the refraction layer is a metal film deposited at the bottom of the second recessed pattern.

10. The template according to claim 8, wherein the refraction layer is a metal layer formed by implanting metal ions into the template substrate at the bottom of the second recessed pattern.

11. The template according to claim 8, wherein the third recessed pattern has a depth equal to a depth of the first recessed pattern and a depth of the second recessed pattern.

12. The template according to claim 8, wherein the third recessed pattern has a depth larger than a depth of the first recessed pattern and a depth of the second recessed pattern.

13. The template according to claim 8, wherein
the device formation pattern, the alignment mark, and the filling monitor mark are arranged in a pattern arrangement region provided in the template substrate, and
the alignment mark and the filling monitor mark are arranged at each of four corners of the pattern arrangement region.
